(19) United States
(12) Patent Application Publication
(10) Pub. No.: US 2009/0020823 A1
(43) Pub. Date: Jan. 22, 2009

(54) SEMICONDUCTOR DEVICE AND METHOD FOR MANUFACTURING THE SAME

(76) Inventor: Tomohiro Fujita, Hyogo (JP)

Correspondence Address: MCDERMOTT WILL & EMERY LLP, 600 13TH STREET, NW, WASHINGTON, DC, 20005-3096, US

(21) Appl. No.: 12/166,081

(22) Filed: Jul. 1, 2008

(30) Foreign Application Priority Data
Jul. 20, 2007 (JP) 2007-189553

(51) Int. Cl. H01L 27/092; H01L 21/31

(52) U.S. Cl. 257/369; 438/621; 257/E27.064; 257/E21.24; 257/E21.294; 257/E21.241

(57) ABSTRACT

A semiconductor device of the present invention includes a first transistor, a first stress-inducing film, a first insulating film, and a second insulating film. The first transistor is formed in a first active region of a semiconductor substrate, and includes a first gate electrode. The first stress-inducing film is formed so as to cover the first gate electrode, and applies a stress to the channel region of the first transistor. The first insulating film is formed on the first stress-inducing film and has a planarized upper surface. The second insulating film is formed on the first insulating film.

### CROSS REFERENCE TO RELATED APPLICATION

This application claims priority under 35 U.S.C. §119 on Patent Application No. 2007-189553 filed in Japan on Jul. 20, 2007, the entire contents of which are hereby incorporated by reference.

### BACKGROUND OF THE INVENTION

1. Field of the Invention

The present invention relates to a semiconductor device and a method for manufacturing the same, and more particularly to a semiconductor device including an n-type transistor and a p-type transistor on the same substrate, and a method for manufacturing the same.

2. Description of the Background Art

Field effect transistors such as, for example, those called “Metal Insulator Semiconductor Field Effect Transistors” (MISFETs) are known in the art as transistors used in semiconductor devices. MISFETs can easily be integrated with a high degree of integration, and are therefore widely used as circuit elements of integrated circuits.

It is commonly known in the art that the characteristics of MISFETs vary when a stress is applied to the channel region. With an n-type MISFET, the drain current decreases as a compressive stress is applied in the direction in which the drain current Id flows (i.e., the gate length direction), and the drain current increases as a tensile stress is applied in that direction. With a p-type MISFET, the drain current increases as a compressive stress is applied decreases as a tensile stress is applied.

In view of this, a semiconductor device has been proposed in the art (see, for example, Japanese Laid-Open Patent Publication Nos. 2003-273240 and 2003-60076) in which a stress-inducing film being an insulating film having a tensile stress is formed directly above an n-type MISFET and a compressive stress-inducing film is formed directly above a p-type MISFET. Therefore, a tensile stress in the gate length direction is applied to the channel region of the n-type MISFET and a compressive stress in the gate length direction is applied to the channel region of the p-type MISFET, and it is expected that the drain current increases both in the n-type MISFET and in the p-type MISFET.

However, the following problem occurs with a conventional semiconductor device including a tensile stress-inducing film and a compressive stress-inducing film.

The formation of insulating films of different characteristics over the n-type MISFET and over the p-type MISFET requires the following steps. For example, after a first stress-inducing film having a tensile stress is formed across the entire surface of the substrate, a portion of the first stress-inducing film in which a p-type MISFET is to be formed is selectively removed. Then, after a second stress-inducing film having a compressive stress is formed across the entire surface of the substrate, a portion of the second stress-inducing film in which an n-type MISFET is to be formed is selectively removed. However, it is difficult to completely remove the second stress-inducing film, which has been formed on the first stress-inducing film. Especially, where there are only small intervals between gate electrodes, the second insulating film may fill in the gaps between the gate electrodes, thereby making the thickness of the second insulating film uneven. As a result, portions of the second insulating film remain on the first insulating film on the side surface of the gate electrode of the n-type MISFET.

When a tensile stress-inducing film and a compressive stress-inducing film are layered on each other, the stresses are canceled out by each other, thus failing to improve the drain current, or even decreasing the drain current.

### SUMMARY OF THE INVENTION

It is an object of the present invention to realize a semiconductor device in which the stress of an insulating film having a compressive stress and that of an insulating film having a tensile stress are not canceled out by each other.

In order to achieve the object set forth above, the semiconductor device of the present invention includes an insulating film covering a stress-inducing film and having a planarized upper surface.

Specifically, a semiconductor device of the present invention includes: a first transistor of a first conductivity type having a first gate electrode formed above a first active region of a semiconductor substrate; a first stress-inducing film formed over the first active region so as to cover the first gate electrode for applying a stress to a channel region of the first transistor; a first insulating film formed on the first stress-inducing film and having a planar upper surface; and a second insulating film formed on the first insulating film.

In the semiconductor device of the present invention, the first insulating film is formed on the first stress-inducing film, and the upper surface of the first insulating film is planarized. Therefore, after forming the second stress-inducing film for applying a stress to the channel region of the second transistor, it is easy to completely remove unnecessary portions of the second stress-inducing film. Thus, there is little possibility for the drain current of the transistor to decrease due to the stress from the first stress-inducing film and that from the second stress-inducing film canceling out each other.

A method for manufacturing a semiconductor device of the present invention includes: a step (a) of forming a first transistor having a first gate electrode above a first active region of a semiconductor substrate and forming a second transistor having a second gate electrode above a second active region; a step (b) of forming a first stress-inducing film over the semiconductor substrate so as to cover the first gate electrode and the second gate electrode; a step (c) of forming a first insulating film over the semiconductor substrate so as to cover the first stress-inducing film and then planarizing an upper surface of the formed first insulating film; a step (d) of selectively removing a portion of the first insulating film and a portion of the first stress-inducing film that are formed above the second active region; a step (e) of forming a second stress-inducing film over the semiconductor substrate so as to cover the second gate electrode and the first insulating film; a step (f) of selectively removing a portion of the second stress-inducing film that is formed above the first active region; and a step (g) of forming a second insulating film so as to cover the first insulating film and the second stress-inducing film.

With the method for manufacturing a semiconductor device of the present invention, a portion of the second stress-inducing film that is formed in the first region has a substantially constant thickness and is planar. Therefore, in the process of selectively removing a portion of the second stress-inducing film that is formed in the first region, it is easy to completely remove the portion. As a result, it is possible to realize a semiconductor device, in which the stress from the insulating film having a compressive stress and that from the insulating film having a tensile stress will not cancel out each other, and the drain current will not decrease.

### BRIEF DESCRIPTION OF THE DRAWINGS

FIG. 1 is a cross-sectional view showing a semiconductor device according to one embodiment of the present invention.

FIGS. 2A and 2B are cross-sectional views sequentially showing steps of a method for manufacturing a semiconductor device according to one embodiment of the present invention.

FIGS. 3A and 3B are cross-sectional views sequentially showing steps of the method for manufacturing a semiconductor device according to one embodiment of the present invention.

FIGS. 4A and 4B are cross-sectional views sequentially showing steps of the method for manufacturing a semiconductor device according to one embodiment of the present invention.

FIGS. 5A and 5B are cross-sectional views sequentially showing steps of the method for manufacturing a semiconductor device according to one embodiment of the present invention.

FIG. 6 is a cross-sectional view showing a variation of the semiconductor device according to one embodiment of the present invention.

FIG. 7 is a cross-sectional view showing a variation of the semiconductor device according to one embodiment of the present invention.

FIG. 8 is a cross-sectional view showing a variation of the semiconductor device according to one embodiment of the present invention.

### DESCRIPTION OF THE PREFERRED EMBODIMENTS

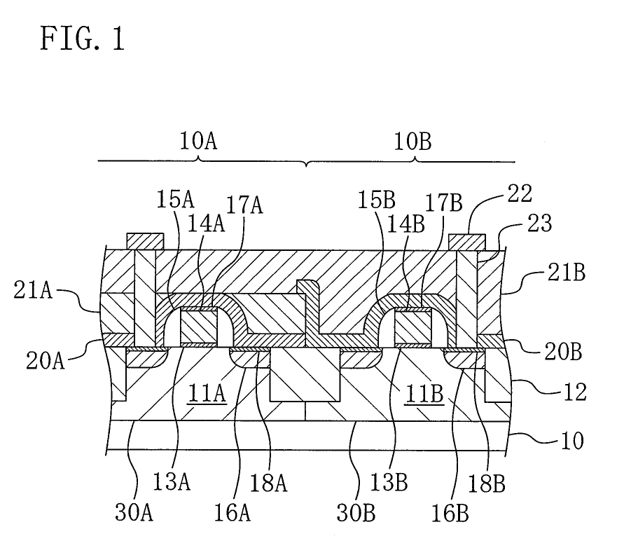

One embodiment of the present invention will now be described with reference to the drawings. FIG. 1 shows a cross section of a semiconductor device according to one embodiment of the present invention.

Referring to FIG. 1, an n-type transistor being a first transistor is formed in a first region 10A of a semiconductor substrate 10, and a p-type transistor being a second transistor is formed in a second region 10B of the semiconductor substrate 10. In the present embodiment, the n-type transistor and the p-type transistor are both a MISFET.

The first region 10A includes a device isolation region 12 such as a shallow trench isolation (STI), and a first active region 11A being a portion of the semiconductor substrate 10 surrounded by the device isolation region 12. The second region 10B includes the device isolation region 12 such as a shallow trench isolation (STI), and a second active region 11B being a portion of the semiconductor substrate 10 surrounded by the device isolation region 12.

The n-type transistor includes a first gate electrode 14A formed above the first active region 11A provided in the first region 10A, and n-type source/drain diffusion layers 16A formed in the first active region 11A. The first gate electrode 14A is formed by single crystal silicon having a thickness of about 100 nm. A first gate insulating film 13A is formed between the first gate electrode 14A and the first active region 11A. A silicide layer 17A is formed on the first gate electrode 14A. A first sidewall 15A is formed on the side surface of the first gate electrode 14A. The n-type source/drain diffusion layers 16A are formed in regions of the first active region 11A on opposite sides of the first sidewall 15A. A silicide layer 18A is formed in an upper portion of the n-type source/drain diffusion layer 16A. An n-type extension region (not shown) is provided in a portion of the first active region 11A beside and below the first gate electrode 14A.

The p-type transistor includes a second gate electrode 14B formed above the second active region 11B provided in the second region 10B, and p-type source/drain diffusion layers 16B formed in the second active region 11B. The second gate electrode 14B is formed by single crystal silicon having a thickness of about 100 nm. A second gate insulating film 13B is formed between the second gate electrode 14B and the second active region 11B. A silicide layer 17B is formed on the second gate electrode 14B. A second sidewall 15B is formed on the side surface of the second gate electrode 14B. The p-type source/drain diffusion layers 16B are formed in regions of the second active region 11B on opposite sides of the second sidewall 15B. A silicide layer 18B is formed in an upper portion of the p-type source/drain diffusion layer 16B. A p-type extension region (not shown) is provided in a portion of the second active region 11B beside and below the second gate electrode 14B.

A first stress-inducing film 20A is formed over the first active region 11A so as to cover the first gate electrode 14A and the first sidewall 15A. A first insulating film 21A of SiO₂, or the like, is formed on the first stress-inducing film 20A. The upper surface of the first insulating film 21A is planarized. While FIG. 1 shows a portion of the first stress-inducing film 20A above the first gate electrode 14A being exposed through the first insulating film 21A, it is not necessary that this portion of the first stress-inducing film 20A is exposed.

A second stress-inducing film 20B is formed on the second active region 11B so as to cover the second gate electrode 14B and the second sidewall 15B. A second insulating film 21B being SiO₂, or the like, is formed over the first active region 11A and the second active region 11B. The second insulating film 21B is in contact with the first insulating film 21A above the first active region 11A, and is in contact with the second stress-inducing film 20B above the second active region 11B.

Metal interconnects 22 are formed on the second insulating film 21B, and are connected to the silicide layer 18A and the silicide layer 18B by contact plugs 23. Contact plugs and metal interconnects connected to the silicide layer 17A and the silicide layer 17B may be formed as necessary.

The first stress-inducing film 20A and the second stress-inducing film 20B are insulating films of silicon nitride (SiN), or the like, and have stresses of different natures from each other. With an appropriate adjustment of the deposition conditions, the first stress-inducing film 20A applies a tensile stress in the gate length direction of the first gate electrode 14A to the first active region 11A, and the second stress-inducing film 20B applies a compressive stress in the gate length direction of the second gate electrode 14B to the second active region 11B.

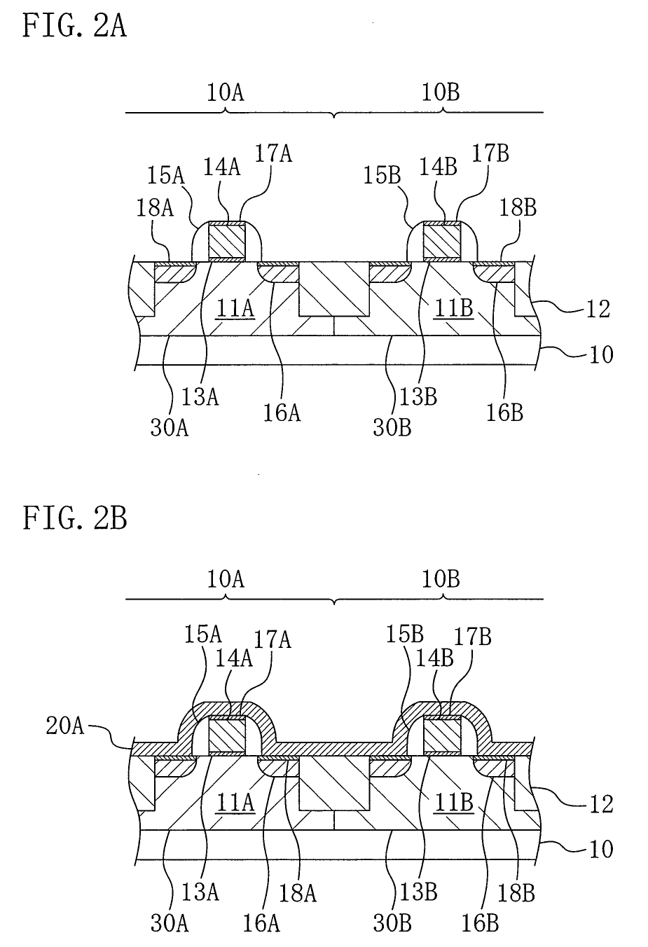

FIGS. 2A to 5B sequentially show steps of a method for manufacturing a semiconductor device according to one embodiment of the present invention. First, referring to FIG. 2A, an n-type transistor being a first transistor is formed in the first region 10A of the semiconductor substrate 10, and a p-type transistor being a second transistor is formed in the second region 10B. The n-type transistor includes the first gate electrode 14A formed above the first active region 11A, in which the p-type well is formed, with the first gate insulating film 13A being interposed therebetween, the silicide layer 17A formed on the first gate electrode 14A, the first sidewall 15A formed on the side surface of the first gate electrode 14A, the n-type source/drain diffusion layer 16A formed beside and below the first sidewall 15A in the first active region 11A, and the silicide layer 18A formed on the n-type source/drain diffusion layer 16A. The p-type transistor includes the second gate electrode 14B formed above the second active region 11B, in which the n-type well is formed, with the second gate insulating film 13B being interposed therebetween, the silicide layer 17B formed on the second gate electrode 14B, the second sidewall 15B formed on the side surface of the second gate electrode 14B, the p-type source/drain diffusion layer 16B formed beside and below the second sidewall 15B in the second active region 11B, and the silicide layer 18B formed on the p-type source/drain diffusion layer 16B.

Then, referring to FIG. 2B, the first stress-inducing film 20A is deposited over the semiconductor substrate 10 so as to cover the first gate electrode 14A, the first sidewall 15A, the second gate electrode 14B and the second sidewall 15B. The first stress-inducing film 20A, which is a silicon nitride (SiN) film having a thickness of 30 nm and formed by a plasma CVD (chemical vapor deposition), for example, applies a tensile stress in the gate length direction of the first gate electrode 14A to the first active region 11A.

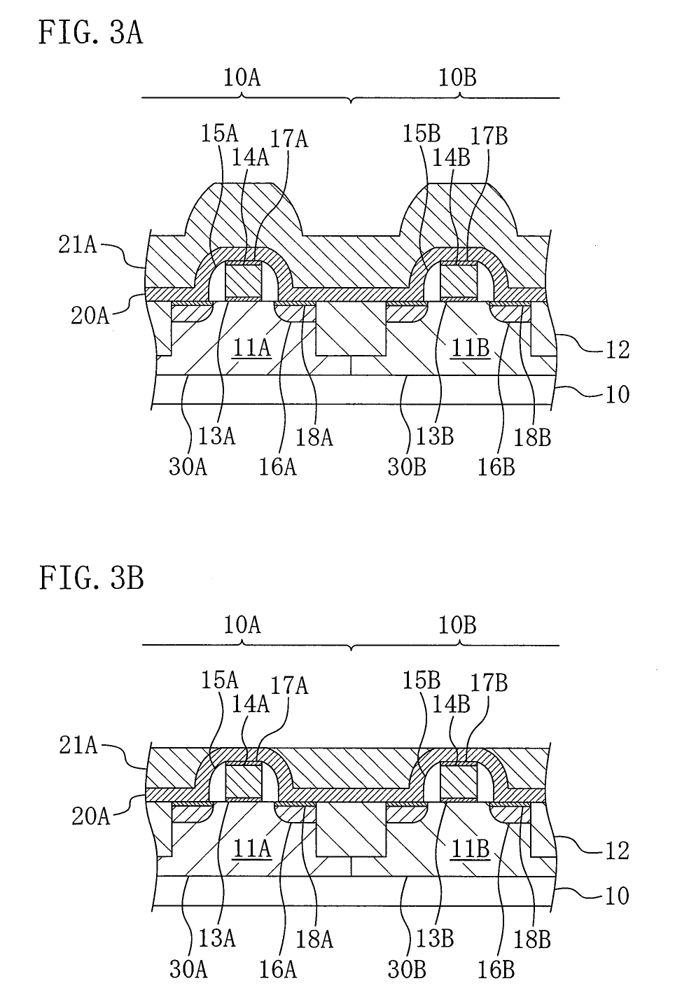

Then, referring to FIG. 3A, the first insulating film 21A is formed over the semiconductor substrate 10 so as to cover the first stress-inducing film 20A. The first insulating film 21A is an SiO₂ film having a thickness of 150 nm, for example.

Then, referring to FIG. 3B, the first insulating film 21A is subjected to an anisotropic etching such as a reactive ion etching (RIE), thereby planarizing the upper surface of the first insulating film 21A and exposing a portion of the first stress-inducing film 20A above the first gate electrode 14A and a portion thereof above the second gate electrode 14B.

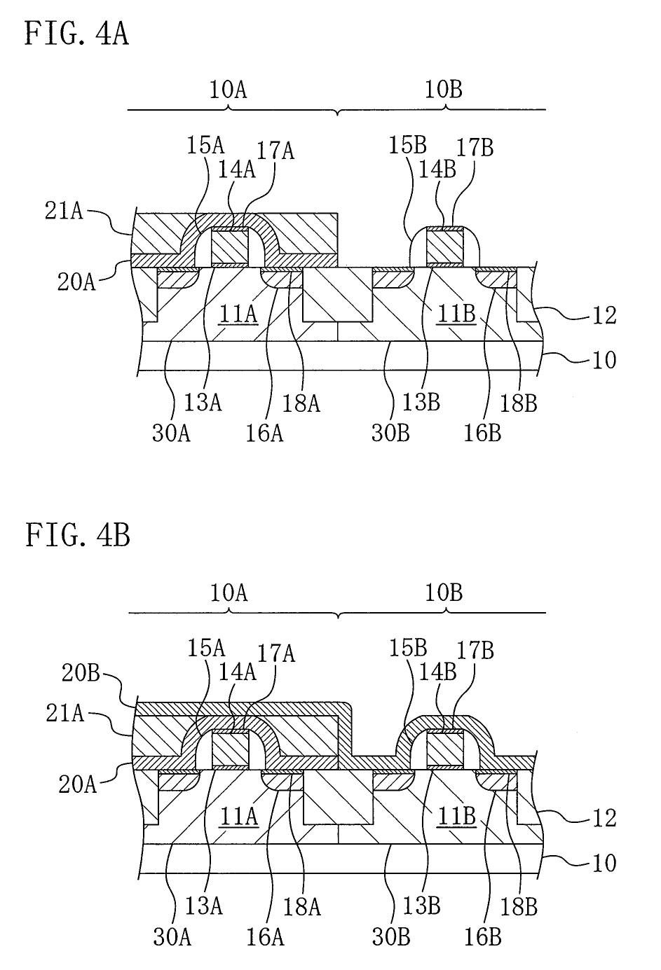

Then, referring to FIG. 4A, a portion of the first insulating film 21A and a portion of the first stress-inducing film 20A that are formed in the second region 10B are selectively removed by using lithography and RIE. As a result, the first stress-inducing film 20A and the first insulating film 21A remain above the first active region 11A.

Then, referring to FIG. 4B, the second stress-inducing film 20B is formed over the semiconductor substrate 10 so as to cover the second gate electrode 14B, the second sidewall 15B and the first insulating film 21A. The second stress-inducing film 20B, which is an SiN film having a thickness of 30 nm and formed by a plasma CVD, for example, applies a tensile stress in the gate length direction of the second gate electrode 14B to the second active region 11B.

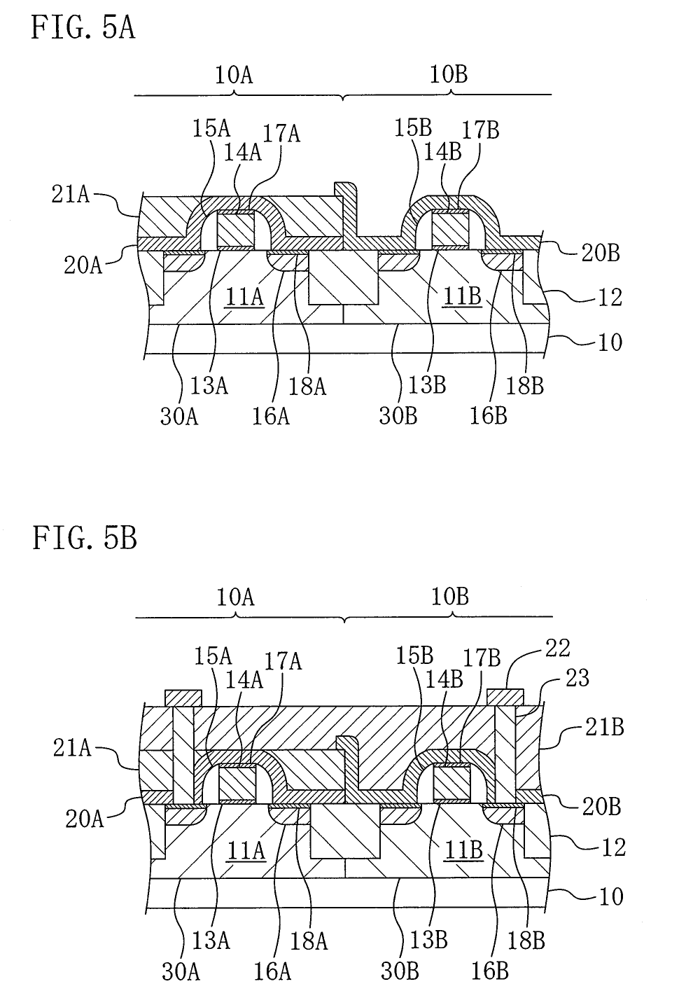

Then, referring to FIG. 5A, a portion of the second stress-inducing film 20B that is formed in the first region 10A, i.e., a portion that is formed above the first active region 11A, is selectively removed by using lithography and RIE. In the first region 10A, the upper surface of the first insulating film 21A is planarized. Therefore, a portion of the second stress-inducing film 20B that is formed above the first active region 11A has a substantially uniform thickness, and substantially no etching residue is produced therein. Therefore, there is little decrease in the drain current of the n-type transistor due to the stress of the first stress-inducing film 20A and that of the second stress-inducing film 20B canceling out each other.

Then, referring to FIG. 5B, the second insulating film 21B of SiO₂, or the like, is formed across the entire surface of the semiconductor substrate 10 so as to cover the first insulating film 21A and the second stress-inducing film 20B. Then, after the upper surface of the second insulating film 21B is planarized by using a chemical mechanical polishing (CMP) method, or the like, the metal interconnects 22, the contact plugs 23, etc., are formed by using known methods.

The first insulating film 21A may be an NSG (Nondope Silicate Glass) film having a tensile stress, and the second insulating film 21B may be a BPSG (Boro-Phospho-Silicate Glass) film having a compressive stress. Alternatively, the first insulating film 21A and the second insulating film 21B may be formed as a film having a tensile stress and a film having a compressive stress, respectively, by varying the method of formation between the first insulating film 21A and the second insulating film 21B, instead of varying the film material therebetween. The first insulating film 21A may be a film having a tensile stress as is the first stress-inducing film 20A, and the second insulating film 21B may be a film having a compressive stress as is the second stress-inducing film 20B, whereby it is possible to apply a greater tensile stress to the first active region 11A of the n-type transistor and a greater compressive stress to the second active region 11B of the p-type transistor, thus further improving the drain current.

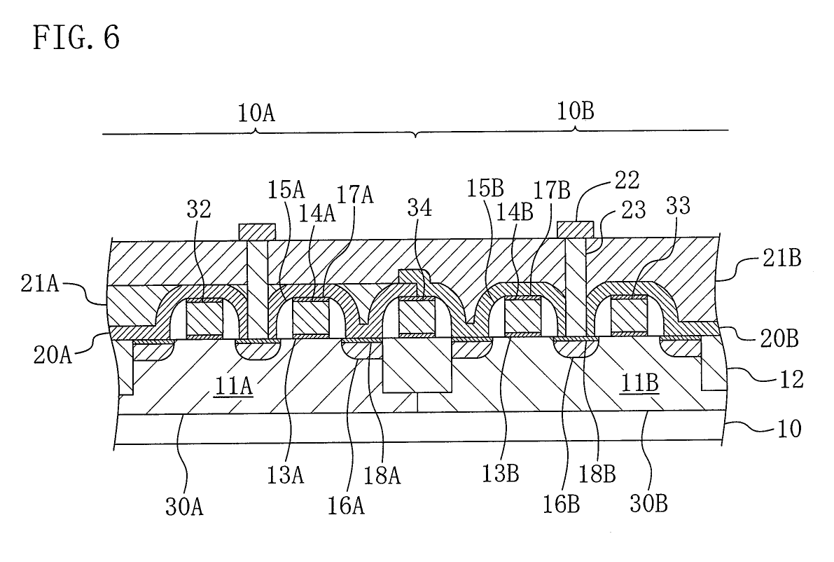

The semiconductor device of the present embodiment may include conductive patterns besides the gate electrodes. The conductive patterns include gate electrodes, gate interconnects, dummy electrodes, etc., and are formed over the semiconductor substrate, opposing the gate electrodes. For example, referring to FIG. 6, a conductive pattern 32 and a conductive pattern 33 being the gate electrodes of different transistors are formed in the first region 10A and the second region 10B, and a conductive pattern 34 being a gate interconnect is formed above the device isolation region 12, which is a boundary region between the first region 10A and the second region 10B.

Where such conductive patterns are formed, opposing the first gate electrode 14A, if the second stress-inducing film 20B fills in the gap between the first gate electrode 14A and the conductive pattern 32 or between the first gate electrode 14A and the conductive pattern 34, it becomes difficult to completely remove the second stress-inducing film 20B. However, the semiconductor device of the present embodiment includes the first insulating film 21A formed on the first stress-inducing film 20A and having a planarized upper surface. Therefore, the second stress-inducing film 20B will not fill in the gap between the first gate electrode 14A and the conductive pattern 32 or between the first gate electrode 14A and the conductive pattern 34, whereby it is possible to form the second stress-inducing film 20B with a uniform thickness. Thus, it is possible to easily remove a portion of the second stress-inducing film 20B that is formed in the first region 10A. As a result, the drain current of the n-type transistor will not decrease due to the second stress-inducing film 20B remaining above the first active region 11A.

The first insulating film 21A may be planarized by a CMP method, instead of etching. In such a case, the endpoint of the CMP process can be detected based on the portion of the first stress-inducing film 20A formed above the first gate electrode 14A, whereby it is possible to easily control the thickness of the first insulating film 21A.

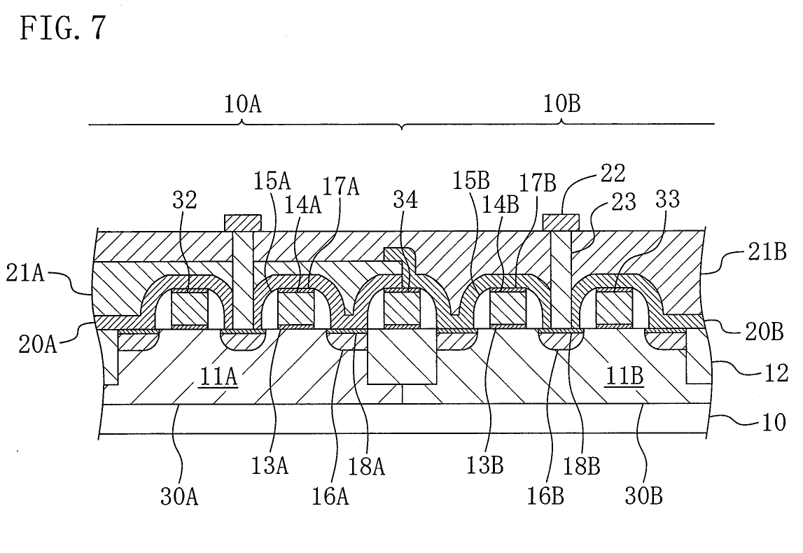

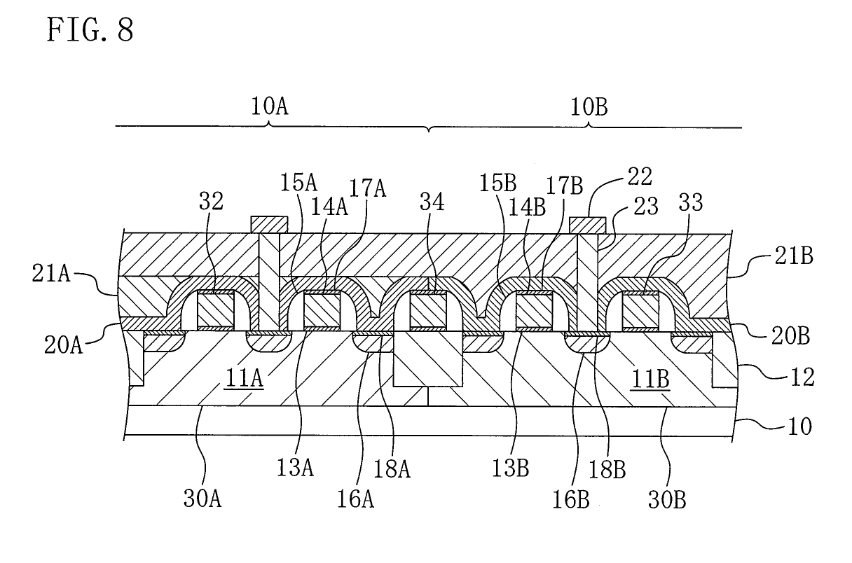

Referring to FIG. 7, the process of planarizing the first insulating film 21A may be stopped before the upper portion of the first stress-inducing film 20A is exposed, whereby the first insulating film 21A completely covers the first stress-inducing film 20A. Then, in the process of removing the second stress-inducing film 20B, it is possible to prevent the first stress-inducing film 20A from being etched due to overetching.

Where the second stress-inducing film 20B is removed by etching, the etching mask needs to be given a margin, thus resulting in an area along the boundary between the first region 10A and the second region 10B where the first stress-inducing film 20A and the second stress-inducing film 20B overlap each other. If there is a need to make a connection with the conductive pattern 34, it is preferred that there is no such overlap. In such a case, a planarizing process can be performed by a CMP method, after selectively removing the second stress-inducing film 20B by etching, thereby eliminating an overlap as shown in FIG. 8.

Although the present embodiment has illustrated a case where a tensile stress-inducing film covering the n-type transistor is formed first, a compressive stress-inducing film covering the p-type transistor may be formed first.

The first gate insulating film 13A and the second gate insulating film 13B may be formed by using a common material of a gate insulating film, such as SiO₂, SiN or a high-k material. Nitrogen may be added to SiO₂, or the film may be a layered film including a high-k layer. The first sidewall 15A and the second sidewall 15B may be formed by using SiO₂, SiN, or the like, and may be a layered film. A pocket diffusion layer, or the like, may be formed below the extension diffusion layer, as necessary.

Thus, the present invention, being capable of realizing a semiconductor device in which an insulating film having a compressive stress and an insulating film having a tensile stress will not cancel out each other's stress, is particularly useful as a semiconductor device including an n-type transistor and a p-type transistor on the same substrate, and a method for manufacturing the same.

The description of the embodiments of the present invention is given above for the understanding of the present invention. It will be understood that the invention is not limited to the particular embodiments described herein, but is capable of various modifications, rearrangements and substitutions as will now become apparent to those skilled in the art without departing from the scope of the invention. Therefore, it is intended that the following claims cover all such modifications and changes as fall within the true spirit and scope of the invention.

What is claimed is:

1. A semiconductor device, comprising:
a first transistor of a first conductivity type having a first gate electrode formed above a first active region of a semiconductor substrate;
a first stress-inducing film formed over the first active region so as to cover the first gate electrode for applying a stress to a channel region of the first transistor;
a first insulating film formed on the first stress-inducing film and having a planar upper surface; and
a second insulating film formed on the first insulating film.

2. The semiconductor device of claim 1, wherein the first insulating film is absent above the first gate electrode.

3. The semiconductor device of claim 1, wherein the first insulating film is a film that applies no stress to the channel region of the first transistor.

4. The semiconductor device of claim 1, wherein the first insulating film is a film that applies, to the channel region of the first transistor, a stress of the same nature as that applied by the first stress-inducing film.

5. The semiconductor device of claim 1, wherein:
the first transistor is an n-type MISFET; and
the first stress-inducing film is a film that applies a tensile stress in a gate length direction to the channel region of the first transistor

6. The semiconductor device of claim 1, wherein:
the first transistor is a p-type MISFET; and
the first stress-inducing film is a film that applies a compressive stress in the gate length direction to the channel region of the first transistor.

7. The semiconductor device of claim 1, further comprising:
a second transistor of a second conductivity type having a second gate electrode formed above a second active region of the semiconductor substrate; and
a second stress-inducing film formed over the second active region so as to cover the second gate electrode for applying a stress of a different nature than that applied by the first stress-inducing film to a channel region of the second transistor,
wherein the second insulating film is formed on the second stress-inducing film and the first insulating film.

8. The semiconductor device of claim 7, wherein the second insulating film is a film that applies, to the channel region of the second transistor, a stress of the same nature as that applied by the second stress-inducing film.

9. The semiconductor device of claim 7, wherein:
the first transistor is an n-type MISFET;
the second transistor is a p-type MISFET;
the first stress-inducing film is a film that applies a tensile stress in a gate length direction to the channel region of the first transistor; and
the second stress-inducing film is a film that applies a compressive stress in the gate length direction to the channel region of the second transistor.

10. The semiconductor device of claim 7, wherein:
the first transistor is a p-type MISFET;
the second transistor is an n-type MISFET;
the first stress-inducing film is a film that applies a compressive stress in a gate length direction to the channel region of the first transistor; and
the second stress-inducing film is a film that applies a tensile stress in the gate length direction to the channel region of the second transistor.

11. The semiconductor device of claim 7, further comprising a first conductive pattern formed above a device isolation region between the first active region and the second active region, wherein:
a portion of the first conductive pattern that is formed on a side of the first active region is covered by the first stress-inducing film;
a portion of the first conductive pattern that is formed on a side of the second active region is covered by the second stress-inducing film; and
the first stress-inducing film and the second stress-inducing film are planarized above the first conductive pattern.

12. The semiconductor device of claim 1, further comprising a second conductive pattern formed above the first active region so as to oppose the first gate electrode, wherein:
the first stress-inducing film covers the second conductive pattern; and
the first insulating film fills in a gap between the first gate electrode and the second conductive pattern.

13. The semiconductor device of claim 12, wherein the second conductive pattern is a gate electrode of a third transistor formed above the first active region.

14. A method for manufacturing a semiconductor device, the method comprising:
a step (a) of forming a first transistor having a first gate electrode above a first active region of a semiconductor substrate and forming a second transistor having a second gate electrode above a second active region;
a step (b) of forming a first stress-inducing film over the semiconductor substrate so as to cover the first gate electrode and the second gate electrode;
a step (c) of forming a first insulating film over the semiconductor substrate so as to cover the first stress-inducing film and then planarizing an upper surface of the formed first insulating film;
a step (d) of selectively removing a portion of the first insulating film and a portion of the first stress-inducing film that are formed above the second active region;
a step (e) of forming a second stress-inducing film over the semiconductor substrate so as to cover the second gate electrode and the first insulating film;
a step (f) of selectively removing a portion of the second stress-inducing film that is formed above the first active region; and
a step (g) of forming a second insulating film so as to cover the first insulating film and the second stress-inducing film.

15. The method for manufacturing a semiconductor device of claim 14, wherein the step (c) includes planarizing the first insulating film so that a portion of the first stress-inducing film that is formed above the first gate electrode is exposed through the first insulating film.

16. The method for manufacturing a semiconductor device of claim 14, wherein:
the step (a) includes forming a first conductive pattern above a device isolation region provided between the first active region and the second active region; and
the step (f) includes removing and planarizing a portion of the second stress-inducing film that is formed on the first stress-inducing film above the first conductive pattern by using a chemical mechanical polishing method.

17. The method for manufacturing a semiconductor device of claim 14, wherein:
the step (a) includes forming a second conductive pattern opposing the first gate electrode above the first active region; and
the step (c) includes forming the first insulating film so that the first insulating film fills in a gap between the first gate electrode and the first conductive pattern.

18. The method for manufacturing a semiconductor device of claim 14, wherein:
the first stress-inducing film is formed so as to apply a tensile stress in a gate length direction to a channel region formed under the first gate electrode; and
the second stress-inducing film is formed so as to apply a compressive stress in the gate length direction to a channel region formed under the second gate electrode.

19. The method for manufacturing a semiconductor device of claim 14, wherein:
the first stress-inducing film is formed so as to apply a compressive stress in a gate length direction to a channel region formed under the first gate electrode; and
the second stress-inducing film is formed so as to apply a tensile stress in the gate length direction to a channel region formed under the second gate electrode.

20. The method for manufacturing a semiconductor device of claim 19, wherein:
the first insulating film is formed so as to apply a stress of the same nature as that applied by the first stress-inducing film to a channel region formed under the first gate electrode; and
the second insulating film is formed so as to apply a stress of the same nature as that applied by the second stress-inducing film to a channel region formed under the second gate electrode.
